(19) United States
(12) Patent Application Publication
(10) Pub. No.: US 2015/0175805 A1
(43) Pub. Date: Jun. 25, 2015

(54) Polyarylene Sulfide Composition for Use in Forming a Laser Direct Structured Substrate

(71) Applicant: Ticona LLC, Florence, KY (US)

(72) Inventor: Michael Schaefer, Maintal (DE)

(21) Appl. No.: 14/564,276

(22) Filed: Dec. 9, 2014

Related U.S. Application Data
(60) Provisional application No. 61/918,098, filed on Dec. 19, 2013.

(51) Int. Cl. C08L 81/04; H05K 1/03; H05K 3/18

(52) U.S. Cl. CPC C08L 81/04; H05K 3/182; H05K 1/0373; C08L 2205/12; C08L 2203/20; H05K 2203/107; H05K 2203/11; C08L 2310/00

(57) ABSTRACT

A polymer composition formed from a polyarylene sulfide matrix that constitutes a majority of the polymer content of the composition is provided. Although polyarylene sulfides are not typically capable of laser activation, particularly at such a high content of the polymer composition, the present inventor has nevertheless discovered that the resulting composition can still be readily activated with one or more conductive elements using a laser direct structuring process. This is accomplished, in part, by dispersing a combination of a condensation polymer and laser activatable additive within the polyarylene sulfide matrix.

### RELATED APPLICATIONS

The present application claims priority to U.S. Provisional Application Ser. No. 61/918,098, filed on Dec. 19, 2013, which is incorporated herein in its entirety by reference thereto.

### BACKGROUND OF THE INVENTION

It is becoming increasingly more common to form metallized electronic components with a laser direct structuring (“LDS”) process during which a computer-controlled laser beam travels over a plastic substrate to activate its surface at locations where the conductive path is to be situated. For example, molded interconnect devices (“MID”) often contain a plastic substrate on which is formed conductive elements or pathways. Such MID devices are thus three-dimensional molded parts having an integrated printed conductor or circuit layout, which saves space for use in smaller devices (e.g., cellular phones). Besides saving space, another advantage of laser direct structuring is its flexibility. If the design of the circuit is changed, it is simply a matter of reprogramming the computer that controls the laser. This greatly reduces the time and cost from prototyping to producing a final commercial product. Various materials have been proposed for forming the plastic substrate of a laser direct structured device. For example, one such material is a blend of polycarbonate, acrylonitrile butadiene styrene (“ABS”), copper chromium oxide spinel, and a bisphenol A diphenyl phosphate (“BPADP”) flame retardant. One problem with such materials, however, is that they are unsuitable for lead free soldering processes (surface mount technology) that require high temperature resistance. The flame retardant also tends to adversely impact the mechanical properties (e.g., deformation temperature under load) of the composition, which makes it difficult to use in laser direct structuring processes.

As such, a need exists for a polymer composition that can be activated by laser direct structuring, but still maintain excellent thermal and mechanical properties.

### SUMMARY OF THE INVENTION

In accordance with one embodiment of the present invention, a polymer composition is disclosed that comprises a polyarylene sulfide matrix within which is dispersed a condensation polymer and a laser activatable additive, wherein the polyarylene sulfide matrix constitutes about 30 wt. % or more of the polymer content of the composition.

Other features and aspects of the present invention are set forth in greater detail below.

### BRIEF DESCRIPTION OF THE FIGURES

A full and enabling disclosure of the present invention, including the best mode thereof to one skilled in the art, is set forth more particularly in the remainder of the specification, including reference to the accompanying figures, in which:

FIGS. 1-2 are respective front and rear perspective views of an electronic component that can employ a laser direct structured substrate formed according to one embodiment of the present invention.

### DETAILED DESCRIPTION

It is to be understood by one of ordinary skill in the art that the present discussion is a description of exemplary embodiments only, and is not intended as limiting the broader aspects of the present invention.

Generally speaking, the present invention is directed to a polymer composition formed from a polyarylene sulfide matrix that constitutes a majority of the polymer content of the composition. That is, the polyarylene sulfide matrix, which may include one or more polyarylene sulfides, constitutes about 30 wt. % or more, in some embodiments from about 40 wt. % to about 90 wt. %, and in some embodiments, from about 50 wt. % to about 80 wt. % of the polymer content of the composition. Although polyarylene sulfides are not typically capable of laser activation, particularly at such a high content of the polymer composition, the present inventor has nevertheless discovered that the resulting composition can still be readily activated with one or more conductive elements using a laser direct structuring process. This is accomplished, in part, by dispersing a combination of a condensation polymer and laser activatable additive within the polyarylene sulfide matrix. Through selective control over the particular type and relative concentration of these additives, as well as the particular manner in which they are dispersed within the matrix, the present inventor has discovered that the resulting composition can be laser activated without sacrificing the beneficial properties imparted by the polyarylene sulfide matrix. For example, the polymer composition can withstand relatively high temperatures without melting. In this regard, the composition typically has a relatively high melting temperature, such as from about 200° C. to about 400° C., in some embodiments from about 225° C. to about 350° C., and in some embodiments, from about 250° C. to about 325° C., such as determined using differential scanning calorimetry in accordance with ISO Test No. 11357.

Various embodiments of the present invention will now be described in further detail.

### I. POLYMER COMPOSITION

A. Polyarylene Sulfide

As indicated above, one or more polyarylene sulfides are employed to form a matrix of the polymer composition. The polyarylene sulfide may be a polyarylene thioether containing repeat units of the formula (I):

—[(Ar¹)ₙ—X]ₘ—[(Ar²)ᵢ—Y]ⱼ—[Ar³)ₖ—Z]ₗ—[Ar⁴)ₒ—W]ₚ— (I)

wherein Ar¹, Ar², Ar³, and Ar⁴ are the same or different and are arylene units of 6 to 18 carbon atoms; W, X, Y, and Z are the same or different and are bivalent linking groups selected from —SO₂—, —S—, —SO—, —CO—, —O—, —COO— or alkylene or alkylidene groups of 1 to 6 carbon atoms and wherein at least one of the linking groups is —S—; and n, m, i, j, k, l, o, and p are independently zero or 1, 2, 3, or 4, subject to the proviso that their sum total is not less than 2. The arylene units Ar¹, Ar², Ar³, and Ar⁴ may be selectively substituted or unsubstituted. Advantageous arylene systems are phenylene, biphenylene, naphthylene, anthracene and phenanthrene. The polyarylene sulfide typically includes more than about 30 mol %, more than about 50 mol %, or more than about 70 mol % arylene sulfide (—S—) units. In one embodiment the polyarylene sulfide includes at least 85 mol % sulfide linkages attached directly to two aromatic rings. In one embodiment, the polyarylene sulfide is a polyphenylene sulfide, defined herein as containing the phenylene sulfide structure —(C₆H₄—S)ₙ— (wherein n is an integer of 1 or more) as a component thereof.

Synthesis techniques that may be used in forming a polyarylene sulfide are generally known in the art. By way of example, a process for producing a polyarylene sulfide can include reacting a material that provides a hydrosulfide ion, e.g., an alkali metal sulfide, with a dihaloaromatic compound in an organic amide solvent. The alkali metal sulfide can be, for example, lithium sulfide, sodium sulfide, potassium sulfide, rubidium sulfide, cesium sulfide or a mixture thereof. When the alkali metal sulfide is a hydrate or an aqueous mixture, the alkali metal sulfide can be processed according to a dehydrating operation in advance of the polymerization reaction. An alkali metal sulfide can also be generated in situ. In addition, a small amount of an alkali metal hydroxide can be included in the reaction to remove or react impurities (e.g., to change such impurities to harmless materials) such as an alkali metal polysulfide or an alkali metal thiosulfate, which may be present in a very small amount with the alkali metal sulfide.

The dihaloaromatic compound can be, without limitation, an o-dihalobenzene, m-dihalobenzene, p-dihalobenzene, dihalotoluene, dihalonaphthalene, methoxy-dihalobenzene, dihalobiphenyl, dihalobenzoic acid, dihalodiphenyl ether, dihalodiphenyl sulfone, dihalodiphenyl sulfoxide or dihalodiphenyl ketone. Dihaloaromatic compounds may be used either singly or in any combination thereof. Specific exemplary dihaloaromatic compounds can include, without limitation, p-dichlorobenzene; m-dichlorobenzene; o-dichlorobenzene; 2,5-dichlorotoluene; 1,4-dibromobenzene; 1,4-dichloronaphthalene; 1-methoxy-2,5-dichlorobenzene; 4,4′-dichlorobiphenyl; 3,5-dichlorobenzoic acid; 4,4′-dichlorodiphenyl ether; 4,4′-dichlorodiphenylsulfone; 4,4-dichlorodiphenylsulfoxide, and 4,4′-dichlorodiphenyl ketone. The halogen atom can be fluorine, chlorine, bromine or iodine, and 2 halogen atoms in the same dihalo-aromatic compound may be the same or different from each other. In one embodiment, o-dichlorobenzene, m-dichlorobenzene, p-dichlorobenzene or a mixture of 2 or more compounds thereof is used as the dihalo-aromatic compound. As is known in the art, it is also possible to use a monohalo compound (not necessarily an aromatic compound) in combination with the dihaloaromatic compound in order to form end groups of the polyarylene sulfide or to regulate the polymerization reaction and/or the molecular weight of the polyarylene sulfide.

The polyarylene sulfide may be a homopolymer or may be a copolymer. By a suitable, selective combination of dihaloaromatic compounds, a polyarylene sulfide copolymer can be formed containing not less than two different units. For instance, in the case where p-dichlorobenzene is used in combination with m-dichlorobenzene or 4,4′-dichlorodiphenylsulfone, a polyarylene sulfide copolymer can be formed containing segments having the structure of formula (II):

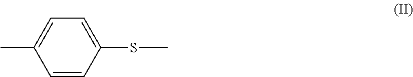

and segments having the structure of formula (III):

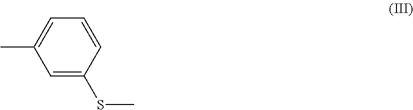

or segments having the structure of formula (IV):

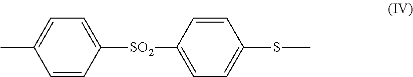

The polymerization reaction may be carried out in the presence of an organic amide solvent. Exemplary organic amide solvents used in a polymerization reaction can include, without limitation, N-methyl-2-pyrrolidone; N-ethyl-2-pyrrolidone; N,N-dimethylformamide; N,N-dimethylacetamide; N-methylcaprolactam; tetramethylurea; dimethylimidazolidinone; hexamethyl phosphoric acid triamide and mixtures thereof. The amount of the organic amide solvent used in the reaction can be, e.g., from 0.2 to 5 kilograms per mole (kg/mol) of the effective amount of the alkali metal sulfide.

The polyarylene sulfide may be linear, semi-linear, branched or crosslinked. A linear polyarylene sulfide includes as the main constituting unit the repeating unit of —(Ar—S)—. In general, a linear polyarylene sulfide may include about 80 mol % or more of this repeating unit. A linear polyarylene sulfide may include a small amount of a branching unit or a cross-linking unit, but the amount of branching or cross-linking units may be less than about 1 mol % of the total monomer units of the polyarylene sulfide. A linear polyarylene sulfide polymer may be a random copolymer or a block copolymer containing the above-mentioned repeating unit.

A semi-linear polyarylene sulfide may be utilized that has a cross-linking or branched structure provided by introducing into the polymer a small amount of one or more monomers having three or more reactive functional groups. For instance, between about 1 mol % and about 10 mol % of the polymer may be formed from monomers having three or more reactive functional groups. Methods that may be used in making semi-linear polyarylene sulfide are generally known in the art. By way of example, monomer components used in forming a semi-linear polyarylene sulfide can include an amount of polyhaloaromatic compounds having 2 or more halogen substituents per molecule which can be utilized in preparing branched polymers. Such monomers can be represented by the formula R′Xₙ, where each X is selected from chlorine, bromine, and iodine, n is an integer of 3 to 6, and R′ is a polyvalent aromatic radical of valence n which can have up to about 4 methyl substituents, the total number of carbon atoms in R′ being within the range of 6 to about 16. Examples of some polyhaloaromatic compounds having more than two halogens substituted per molecule that can be employed in forming a semi-linear polyarylene sulfide include 1,2,3-trichlorobenzene, 1,2,4-trichlorobenzene, 1,3-dichloro-5-bromobenzene, 1,2,4-triiodobenzene, 1,2,3,5-tetrabromobenzene, hexachlorobenzene, 1,3,5-trichloro-2,4,6-trimethylbenzene, 2,2′,4,4′-tetrachlorobiphenyl, 2,2′,5,5′-tetra-iodobiphenyl, 2,2′,6,6′-tetrabromo-3,3′,5,5′-tetramethylbiphenyl, 1,2,3,4-tetrachloronaphthalene, 1,2,4-tribromo-6-methylnaphthalene, and the like, and mixtures thereof.

The polymerization reaction apparatus for forming the polyarylene sulfide is not especially limited, although it is typically desired to employ an apparatus that is commonly used in formation of high viscosity fluids. Examples of such a reaction apparatus may include a stirring tank type polymerization reaction apparatus having a stirring device that has a variously shaped stirring blade, such as an anchor type, a multistage type, a spiral-ribbon type, a screw shaft type and the like, or a modified shape thereof. Further examples of such a reaction apparatus include a mixing apparatus commonly used in kneading, such as a kneader, a roll mill, a Banbury mixer, etc. Following polymerization, the molten polyarylene sulfide may be discharged from the reactor, typically through an extrusion orifice fitted with a die of desired configuration, cooled, and collected. Commonly, the polyarylene sulfide may be discharged through a perforated die to form strands that are taken up in a water bath, pelletized and dried. The polyarylene sulfide may also be in the form of a strand, granule, or powder.

The molecular weight of the polyarylene sulfide is not particularly limited, though in one embodiment, the polyarylene sulfide (which can also encompass a blend of one or more polyarylene sulfide polymers and/or copolymers) may have a relative high molecular weight. For instance a polyarylene sulfide may have a number average molecular weight greater than about 25,000 g/mol, or greater than about 30,000 g/mol, and a weight average molecular weight greater than about 60,000 g/mol, or greater than about 65,000 g/mol.

B. Condensation Polymer

As indicated, the polymer composition of the present invention also contains one or more condensation polymers which, among other things, can enhance the ability of the composition to undergo laser activation. To help achieve a composition that can be laser activated without sacrificing the desirable properties provided by the polyarylene sulfide matrix, the weight ratio of polyarylene sulfides to condensation polymers in the composition may range from about 0.5 to about 10, in some embodiments, from about 1 to about 8, and in some embodiments, from about 2 to about 5. Condensation polymers may, for instance, constitute about 50 wt. % or less, in some embodiments from about 10 wt. % to about 45 wt. %, and in some embodiments, from about 20 wt. % to about 40 wt. % of the polymer content of the composition. The actual concentration of the polymers may generally vary based on the presence of other optional components. Nevertheless, polyarylene sulfides typically constitute from about 15 wt. % to about 75 wt. %, in some embodiments from about 20 wt. % to about 70 wt. %, and in some embodiments, from about 30 wt. % to about 60 wt. % of the polymer composition, while condensation polymers typically constitute from about 1 wt. % to about 30 wt. %, in some embodiments from about 2 wt. % to about 25 wt. %, and in some embodiments, from about 5 wt % to about 20 wt. % of the polymer composition.

Any of a variety of condensation polymers may generally be employed in the polymer composition of the present invention. Examples of such polymers include, for instance, aromatic, aliphatic, and/or aliphatic-aromatic polyesters, polyamides, polyacrylamides, polyimides, etc. In one embodiment, the condensation polymer is an aromatic polyester. One example of such a polymer is a liquid crystalline polymer. The liquid crystalline polymer may be classified as “thermotropic” to the extent that they can possess a rod-like structure and exhibit a crystalline behavior in its molten state (e.g., thermotropic nematic state). Such polymers may be formed from one or more types of repeating units as is known in the art. The liquid crystalline polymer may, for example, contain one or more aromatic ester repeating units, typically in an amount of from about 60 mol. % to about 99.9 mol. %, in some embodiments from about 70 mol. % to about 99.5 mol. %, and in some embodiments, from about 80 mol. % to about 99 mol. % of the polymer. The aromatic ester repeating units may be generally represented by the following Formula (V):

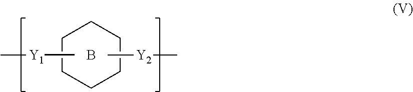

wherein,

ring B is a substituted or unsubstituted 6-membered aryl group (e.g., 1,4-phenylene or 1,3-phenylene), a substituted or unsubstituted 6-membered aryl group fused to a substituted or unsubstituted 5- or 6-membered aryl group (e.g., 2,6-naphthalene), or a substituted or unsubstituted 6-membered aryl group linked to a substituted or unsubstituted 5- or 6-membered aryl group (e.g., 4,4-biphenylene); and

Y₁ and Y₂ are independently O, C(O), NH, C(O)HN, or NHC(O).

Typically, at least one of Y₁ and Y₂ are C(O). Examples of such aromatic ester repeating units may include, for instance, aromatic dicarboxylic repeating units (Y₁ and Y₂ in Formula V are C(O)), aromatic hydroxycarboxylic repeating units (Y₁ is O and Y₂ is C(O) in Formula V), as well as various combinations thereof.

Aromatic dicarboxylic repeating units, for instance, may be employed that are derived from aromatic dicarboxylic acids, such as terephthalic acid, isophthalic acid, 2,6-naphthalenedicarboxylic acid, diphenyl ether-4,4′-dicarboxylic acid, 1,6-naphthalenedicarboxylic acid, 2,7-naphthalenedicarboxylic acid, 4,4′-dicarboxybiphenyl, bis(4-carboxyphenyl)ether, bis(4-carboxyphenyl)butane, bis(4-carboxyphenyl)ethane, bis(3-carboxyphenyl)ether, bis(3-carboxyphenyl)ethane, etc., as well as alkyl, alkoxy, aryl and halogen substituents thereof, and combinations thereof. Particularly suitable aromatic dicarboxylic acids may include, for instance, terephthalic acid (“TA”), isophthalic acid (“IA”), and 2,6-naphthalenedicarboxylic acid (“NDA”). When employed, repeating units derived from aromatic dicarboxylic acids (e.g., IA, TA, and/or NDA) typically constitute from about 5 mol. % to about 60 mol. %, in some embodiments from about 10 mol. % to about 55 mol. %, and in some embodiments, from about 15 mol. % to about 50% of the polymer.

Aromatic hydroxycarboxylic repeating units may also be employed that are derived from aromatic hydroxycarboxylic acids, such as, 4-hydroxybenzoic acid; 4-hydroxy-4′-biphenylcarboxylic acid; 2-hydroxy-6-naphthoic acid; 2-hydroxy-5-naphthoic acid; 3-hydroxy-2-naphthoic acid; 2-hydroxy-3-naphthoic acid; 4′-hydroxyphenyl-4-benzoic acid; 3′-hydroxyphenyl-4-benzoic acid; 4′-hydroxyphenyl-3-benzoic acid, etc., as well as alkyl, alkoxy, aryl and halogen substituents thereof, and combination thereof. Particularly suitable aromatic hydroxycarboxylic acids are 4-hydroxybenzoic acid (“HBA”) and 6-hydroxy-2-naphthoic acid (“HNA”). When employed, repeating units derived from hydroxycarboxylic acids (e.g., HBA and/or HNA) typically constitute from about 10 mol. % to about 85 mol. %, in some embodiments from about 20 mol. % to about 80 mol. %, and in some embodiments, from about 25 mol. % to about 75% of the polymer.

Other repeating units may also be employed in the polymer. In certain embodiments, for instance, repeating units may be employed that are derived from aromatic diols, such as hydroquinone, resorcinol, 2,6-dihydroxynaphthalene, 2,7-dihydroxynaphthalene, 1,6-dihydroxynaphthalene, 4,4′-dihydroxybiphenyl (or 4,4′-biphenol), 3,3′-dihydroxybiphenyl, 3,4′-dihydroxybiphenyl, 4,4′-dihydroxybiphenyl ether, bis(4-hydroxyphenyl)ethane, etc., as well as alkyl, alkoxy, aryl and halogen substituents thereof, and combinations thereof. Particularly suitable aromatic diols may include, for instance, hydroquinone (“HQ”) and 4,4′-biphenol (“BP”). When employed, repeating units derived from aromatic diols (e.g., HQ and/or BP) typically constitute from about 1 mol. % to about 30 mol. %, in some embodiments from about 2 mol. % to about 25 mol. %, and in some embodiments, from about 5 mol. % to about 20% of the polymer. Repeating units may also be employed, such as those derived from aromatic amides (e.g., acetaminophen (“APAP”)) and/or aromatic amines (e.g., 4-aminophenol (“AP”), 3-aminophenol, 1,4-phenylenediamine, 1,3-phenylenediamine, etc.). When employed, repeating units derived from aromatic amides (e.g., APAP) and/or aromatic amines (e.g., AP) typically constitute from about 0.1 mol. % to about 20 mol. %, in some embodiments from about 0.5 mol. % to about 15 mol. %, and in some embodiments, from about 1 mol. % to about 10% of the polymer. It should also be understood that various other monomeric repeating units may be incorporated into the polymer. For instance, in certain embodiments, the polymer may contain one or more repeating units derived from non-aromatic monomers, such as aliphatic or cycloaliphatic hydroxycarboxylic acids, dicarboxylic acids, diols, amides, amines, etc. Of course, in other embodiments, the polymer may be “wholly aromatic” in that it lacks repeating units derived from non-aromatic (e.g., aliphatic or cycloaliphatic) monomers.

In one particular embodiment, the liquid crystalline polymer may be formed from repeating units derived from 4-hydroxybenzoic acid (“HBA”) and terephthalic acid (“TA”) and/or isophthalic acid (“IA”), as well as various other optional constituents. The repeating units derived from 4-hydroxybenzoic acid (“HBA”) may constitute from about 10 mol. % to about 80 mol. %, in some embodiments from about 30 mol. % to about 75 mol. %, and in some embodiments, from about 45 mol. % to about 70% of the polymer. The repeating units derived from terephthalic acid (“TA”) and/or isophthalic acid (“IA”) may likewise constitute from about 5 mol. % to about 40 mol. %, in some embodiments from about 10 mol. % to about 35 mol. %, and in some embodiments, from about 15 mol. % to about 35% of the polymer. Repeating units may also be employed that are derived from 4,4′-biphenol (“BP”) and/or hydroquinone (“HQ”) in an amount from about 1 mol. % to about 30 mol. %, in some embodiments from about 2 mol. % to about 25 mol. %, and in some embodiments, from about 5 mol. % to about 20% of the polymer. Other possible repeating units may include those derived from 6-hydroxy-2-naphthoic acid (“HNA”), 2,6-naphthalenedicarboxylic acid (“NDA”), and/or acetaminophen (“APAP”). In certain embodiments, for example, repeating units derived from HNA, NDA, and/or APAP may each constitute from about 1 mol. % to about 35 mol. %, in some embodiments from about 2 mol. % to about 30 mol. %, and in some embodiments, from about 3 mol. % to about 25 mol. % when employed.

Regardless of the particular constituents and nature of the polymer, the liquid crystalline polymer may be prepared by initially introducing the aromatic monomer(s) used to form ester repeating units (e.g., aromatic hydroxycarboxylic acid, aromatic dicarboxylic acid, etc.) and/or other repeating units (e.g., aromatic diol, aromatic amide, aromatic amine, etc.) into a reactor vessel to initiate a polycondensation reaction. The particular conditions and steps employed in such reactions are well known, and may be described in more detail in U.S. Pat. No. 4,161,470 to Calundann; U.S. Pat. No. 5,616,680 to Linstid, III, et al.; U.S. Pat. No. 6,114,492 to Linstid, III, et al.; U.S. Pat. No. 6,514,611 to Shepherd, et al.; and WO 2004/058851 to Waggoner. The vessel employed for the reaction is not especially limited, although it is typically desired to employ one that is commonly used in reactions of high viscosity fluids. Examples of such a reaction vessel may include a stirring tank-type apparatus that has an agitator with a variably-shaped stirring blade, such as an anchor type, multistage type, spiral-ribbon type, screw shaft type, etc., or a modified shape thereof. Further examples of such a reaction vessel may include a mixing apparatus commonly used in resin kneading, such as a kneader, a roll mill, a Banbury mixer, etc.

If desired, the reaction may proceed through the acetylation of the monomers as known the art. This may be accomplished by adding an acetylating agent (e.g., acetic anhydride) to the monomers. Acetylation is generally initiated at temperatures of about 90° C. During the initial stage of the acetylation, reflux may be employed to maintain vapor phase temperature below the point at which acetic acid byproduct and anhydride begin to distill. Temperatures during acetylation typically range from between 90° C. to 150° C., and in some embodiments, from about 110° C. to about 150° C. If reflux is used, the vapor phase temperature typically exceeds the boiling point of acetic acid, but remains low enough to retain residual acetic anhydride. For example, acetic anhydride vaporizes at temperatures of about 140° C. Thus, providing the reactor with a vapor phase reflux at a temperature of from about 110° C. to about 130° C. is particularly desirable. To ensure substantially complete reaction, an excess amount of acetic anhydride may be employed. The amount of excess anhydride will vary depending upon the particular acetylation conditions employed, including the presence or absence of reflux. The use of an excess of from about 1 to about 10 mole percent of acetic anhydride, based on the total moles of reactant hydroxyl groups present is not uncommon.

Acetylation may occur in a separate reactor vessel, or it may occur in situ within the polymerization reactor vessel. When separate reactor vessels are employed, one or more of the monomers may be introduced to the acetylation reactor and subsequently transferred to the polymerization reactor. Likewise, one or more of the monomers may also be directly introduced to the reactor vessel without undergoing pre-acetylation.

In addition to the monomers and optional acetylating agents, other components may also be included within the reaction mixture to help facilitate polymerization. For instance, a catalyst may be optionally employed, such as metal salt catalysts (e.g., magnesium acetate, tin(I) acetate, tetrabutyl titanate, lead acetate, sodium acetate, potassium acetate, etc.) and organic compound catalysts (e.g., N-methylimidazole). Such catalysts are typically used in amounts of from about 50 to about 500 parts per million based on the total weight of the recurring unit precursors. When separate reactors are employed, it is typically desired to apply the catalyst to the acetylation reactor rather than the polymerization reactor, although this is by no means a requirement.

The reaction mixture is generally heated to an elevated temperature within the polymerization reactor vessel to initiate melt polycondensation of the reactants. Polycondensation may occur, for instance, within a temperature range of from about 250° C. to about 400° C., in some embodiments from about 280° C. to about 395° C., and in some embodiments, from about 300° C. to about 380° C. For instance, one suitable technique for forming the liquid crystalline polymer may include charging precursor monomers and acetic anhydride into the reactor, heating the mixture to a temperature of from about 90° C. to about 150° C. to acetylize a hydroxyl group of the monomers (e.g., forming acetoxy), and then increasing the temperature to from about 250° C. to about 400° C. to carry out melt polycondensation. As the final polymerization temperatures are approached, volatile byproducts of the reaction (e.g., acetic acid) may also be removed so that the desired molecular weight may be readily achieved. The reaction mixture is generally subjected to agitation during polymerization to ensure good heat and mass transfer, and in turn, good material homogeneity. The rotational velocity of the agitator may vary during the course of the reaction, but typically ranges from about 10 to about 100 revolutions per minute (“rpm”), and in some embodiments, from about 20 to about 80 rpm. To build molecular weight in the melt, the polymerization reaction may also be conducted under vacuum, the application of which facilitates the removal of volatiles formed during the final stages of polycondensation. The vacuum may be created by the application of a suctional pressure, such as within the range of from about 5 to about 30 pounds per square inch (“psi”), and in some embodiments, from about 10 to about 20 psi.

Following melt polymerization, the molten polymer may be discharged from the reactor, typically through an extrusion orifice fitted with a die of desired configuration, cooled, and collected. Commonly, the melt is discharged through a perforated die to form strands that are taken up in a water bath, pelletized and dried. In some embodiments, the melt polymerized polymer may also be subjected to a subsequent solid-state polymerization method to further increase its molecular weight. Solid-state polymerization may be conducted in the presence of a gas (e.g., air, inert gas, etc.). Suitable inert gases may include, for instance, include nitrogen, helium, argon, neon, krypton, xenon, etc., as well as combinations thereof. The solid-state polymerization reactor vessel can be of virtually any design that will allow the polymer to be maintained at the desired solid-state polymerization temperature for the desired residence time. Examples of such vessels can be those that have a fixed bed, static bed, moving bed, fluidized bed, etc. The temperature at which solid-state polymerization is performed may vary, but is typically within a range of from about 250° C. to about 350° C. The polymerization time will of course vary based on the temperature and target molecular weight. In most cases, however, the solid-state polymerization time will be from about 2 to about 12 hours, and in some embodiments, from about 4 to about 10 hours.

Of course, the present invention is by no means limited to the use of liquid crystalline polymers. For example, other suitable aromatic polyesters that may be employed include, but are not limited to, poly(ethylene terephthalate), poly(butylene terephthalate), poly(trimethylene terephthalate), poly(ethylene naphthalate), poly(cyclohexanedimethanol terephthalate), etc. Poly(1,4-cyclohexanedimethanol terephthalate) (“PCT”), for instance, may be particularly suitable for use in the polymer composition.

C. Laser Activatable Additive

The polymer composition of the present invention is “laser activatable” in the sense that it contains an additive that may be activated by a laser direct structuring process. In such a process, the additive is exposed to a laser that causes the release of metals. The laser thus draws the pattern of conductive elements onto the part and leaves behind a roughened surface containing embedded metal particles. These particles act as nuclei for the crystal growth during a subsequent plating process (e.g., copper plating, gold plating, nickel plating, silver plating, zinc plating, tin plating, etc). Laser activatable additives typically constitute from about 0.5 wt. % to about 30 wt. %, in some embodiments from about 1 wt. % to about 20 wt. %, and in some embodiments, from about 5 wt. % to about 15 wt. % of the polymer composition.

The laser activatable additive generally includes spinel crystals, which may include two or more metal oxide cluster configurations within a definable crystal formation. For example, the overall crystal formation may have the following general formula:

AB₂O₄

wherein,

A is a metal cation having a valance of 2, such as cadmium, chromium, manganese, nickel, zinc, copper, cobalt, iron, magnesium, tin, titanium, etc., as well as combinations thereof; and

B is a metal cation having a valance of 3, such as chromium, iron, aluminum, nickel, manganese, tin, etc., as well as combinations thereof.

Typically, A in the formula above provides the primary cation component of a first metal oxide cluster and B provides the primary cation component of a second metal oxide cluster. These oxide clusters may have the same or different structures. In one embodiment, for example, the first metal oxide cluster has a tetrahedral structure and the second metal oxide cluster has an octahedral cluster. Regardless, the clusters may together provide a singular identifiable crystal type structure having heightened susceptibility to electromagnetic radiation. Examples of suitable spinel crystals include, for instance, MgAl₂O₄, ZnAl₂O₄, FeAl₂O₄, CuFe₂O₄, CuCr₂O₄, MnFe₂O₄, NiFe₂O₄, TiFe₂O₄, FeCr₂O₄, MgCr₂O₄, etc. Copper chromium oxide (CuCr₂O₄) is particularly suitable for use in the present invention and is available from Shepherd Color Co. under the designation “Shepherd Black 1GM.”

D. Optional Additives

If desired, the composition may optionally contain one or more additives if so desired, such as fillers, flow aids, antimicrobials, pigments, antioxidants, stabilizers, surfactants, waxes, solid solvents, flame retardants, anti-drip additives, and other materials added to enhance properties and processability. For example, a filler material may be incorporated into the polymer composition to enhance strength. Mineral fillers may, for instance, be employed in the polymer composition to help achieve the desired mechanical properties and/or appearance. Mineral fillers may also help enhance the ability of the composition to undergo laser activation. When employed, mineral fillers typically constitute from about 1 wt. % to about 40 wt. %, in some embodiments from about 5 wt. % to about 30 wt. %, and in some embodiments, from about 10 wt. % to about 25 wt. % of the polymer composition. Clay minerals may be particularly suitable for use in the present invention. Examples of such clay minerals include, for instance, talc (Mg₃Si₄O₁₀(OH)₂), halloysite (Al₂Si₂O₅(OH)₄), kaolinite (Al₂Si₂O₅(OH)₄), illite ((K,H₃O)(Al,Mg,Fe)₂(Si,Al)₄O₁₀[(OH)₂, (H₂O]), montmorillonite (Na, Ca)_{0.33}(Al,Mg)₂Si₄O₁₀(OH)₂.nH₂O), vermiculite ((MgFe,Al)₃(Al,Si)₄O₁₀(OH)₂.4H₂O), palygorskite ((Mg,Al)₂Si₄O₁₀(OH).4(H₂O)), pyrophyllite (Al₂Si₄O₁₀(OH)₂), etc., as well as combinations thereof. In lieu of, or in addition to, clay minerals, still other mineral fillers may also be employed. For example, other suitable silicate fillers may also be employed, such as calcium silicate, aluminum silicate, mica, diatomaceous earth, wollastonite, and so forth. Mica, for instance, may be particularly suitable. There are several chemically distinct mica species with considerable variance in geologic occurrence, but all have essentially the same crystal structure. As used herein, the term “mica” is meant to generically include any of these species, such as muscovite (KAl₂(AlSi₃)O₁₀(OH)₂), biotite (K(Mg,Fe)₃(AlSi₃)O₁₀(OH)₂), phlogopite (KMg₃(AlSi₃)O₁₀(OH)₂), lepidolite (K(Li,Al)₂₋₃(AlSi₃)O₁₀(OH)₂), glauconite (K,Na)(Al,Mg,Fe)₂(Si,Al)₄O₁₀(OH)₂), etc., as well as combinations thereof.

A fibrous filler may also be employed to further improve the mechanical properties of the composition. Such fibrous fillers generally have a high degree of tensile strength relative to their mass. For example, the ultimate tensile strength of the fibrous filler (determined in accordance with ASTM D2101) is typically from about 1,000 to about 15,000 Megapascals (“MPa”), in some embodiments from about 2,000 MPa to about 10,000 MPa, and in some embodiments, from about 3,000 MPa to about 6,000 MPa. The high strength fibrous filler may be formed from fibers that are also generally insulative in nature, such as glass, ceramics (e.g., alumina or silica), aramids (e.g., Kevlar® marketed by E. I. Du Pont de Nemours, Wilmington, Del.), polyolefins, polyesters, etc., as well as mixtures thereof. Glass fibers are particularly suitable, such as E-glass, A-glass, C-glass, D-glass, AR-glass, R-glass, S1-glass, S2-glass, etc., and mixtures thereof. When employed, for example, the fibrous filler may constitute from about 1 wt. % to about 40 wt. %, in some embodiments from about 5 wt. % to about 35 wt. %, and in some embodiments, from about 10 wt. % to about 30 wt. % of the polymer composition.

Still other additives that can be included in the composition may include, for instance, antimicrobials, pigments (e.g., carbon black), antioxidants, stabilizers, surfactants, waxes, solid solvents, and other materials added to enhance properties and processability. Lubricants, for instance, may be employed in the polymer composition. Examples of such lubricants include fatty acids esters, the salts thereof, esters, fatty acid amides, organic phosphate esters, and hydrocarbon waxes of the type commonly used as lubricants in the processing of engineering plastic materials, including mixtures thereof. Suitable fatty acids typically have a backbone carbon chain of from about 12 to about 60 carbon atoms, such as myristic acid, palmitic acid, stearic acid, arachic acid, montanic acid, octadecinic acid, parinric acid, and so forth. Suitable esters include fatty acid esters, fatty alcohol esters, wax esters, glycerol esters, glycol esters and complex esters. Fatty acid amides include fatty primary amides, fatty secondary amides, methylene and ethylene bisamides and alkanolamides such as, for example, palmitic acid amide, stearic acid amide, oleic acid amide, N,N′-ethylenebisstearamide and so forth. Also suitable are the metal salts of fatty acids such as calcium stearate, zinc stearate, magnesium stearate, and so forth; hydrocarbon waxes, including paraffin waxes, polyolefin and oxidized polyolefin waxes, and microcrystalline waxes. Particularly suitable lubricants are acids, salts, or amides of stearic acid, such as pentaerythritol tetrastearate, calcium stearate, or N,N′-ethylenebisstearamide. When employed, the lubricant(s) typically constitute from about 0.05 wt. % to about 1.5 wt. %, and in some embodiments, from about 0.1 wt. % to about 0.5 wt. % (by weight) of the polymer composition.

The materials used to form the polymer composition may be combined together using any of a variety of different techniques as is known in the art. In one embodiment, for example, the polyarylene sulfide, condensation polymer, laser activatable additive, and any other optional additives (e.g., mineral filler, fibrous filler, etc.) may be blended together as individual components to form the polymer composition. In other embodiments, however, it may be desirable to pre-blend one or more components together into a masterbatch, which is subsequently blended with other components to form the polymer composition. In one particular embodiment, for example, a masterbatch may be initially formed from the laser activatable additive and condensation polymer. Without intending to be limited by theory, it is believed such a masterbatch can enhance the degree of contact between the laser activatable additive and condensation polymer, and in turn, minimize the degree of contact between the additive and polyarylene sulfide. Because the polyarylene sulfide itself may not be generally laser activatable, it is believed that minimizing its contact with the laser activatable additive can improve the quality of laser activation. Condensation polymers may constitute from about 10 wt. % to about 60 wt. %, in some embodiments from about 15 wt. % to about 50 wt. %, and in some embodiments, from about 20 wt. % to about 40 wt. % of the masterbatch. The laser activatable additive may likewise constitute from about 1 wt. % to about 40 wt. %, in some embodiments from about 5 wt. % to about 30 wt. %, and in some embodiments, from about 10 wt. % to about 20 wt. % of the masterbatch. Other optional additives (e.g., mineral fillers, fibrous fillers, etc.) may also be employed in the masterbatch if desired. When employed, for instance, mineral fillers (e.g., talc) and fibrous fillers (e.g., glass fibers) may each constitute from about 5 wt. % to about 50 wt. %, in some embodiments from about 10 wt. % to about 40 wt. %, and in some embodiments, from about 15 wt. % to about 35 wt. % of the masterbatch.

Regardless of its particular constituents, the resulting masterbatch may be blended with the polyarylene sulfide to form the polymer composition. The masterbatch may be employed in an amount of from about 30 wt. % to about 70 wt. %, in some embodiments from about 40 wt. % to about 60 wt. %, and in some embodiments, from about 45 wt. % to about 65 wt. %, based on the weight of the resulting polymer composition. Polyarylene sulfides may likewise be employed in an amount from about 30 wt. % to about 70 wt. %, in some embodiments from about 40 wt. % to about 60 wt. %, and in some embodiments, from about 45 wt. % to about 65 wt. %, based on the weight of the polymer composition. The components may be blended together in a single-screw or multi-screw extruder at a temperature of from about 250° C. to about 350° C. In one embodiment, the mixture may be melt processed in an extruder that includes multiple temperature zones. The temperature of individual zones are typically set within about −60° C. to about 25° C. relative to the melting temperature of the liquid crystalline polymer. By way of example, the mixture may be melt processed using a twin screw extruder such as a Leistritz 18-mm co-rotating fully intermeshing twin screw extruder. A general purpose screw design can be used to melt process the mixture. In one embodiment, the mixture including all of the components may be fed to the feed throat in the first barrel by means of a volumetric feeder. In another embodiment, different components may be added at different addition points in the extruder, as is known. For example, the polyarylene sulfide may be applied at the feed throat, and the masterbatch may be supplied at the same or different temperature zone located downstream therefrom. Regardless, the resulting mixture can be melted and mixed then extruded through a die. The extruded polymer composition can then be quenched in a water bath to solidify and granulated in a pelletizer followed by drying.

The resulting polymer composition may possess a relatively low melt viscosity, which allows it to be shaped during production of a part. For instance, the composition may have a melt viscosity of about 5000 poise or less, in some embodiments about 3500 poise or less, and in some embodiments, from about 400 to about 2500 poise, as determined by a capillary rheometer at a temperature of about 310° C. and shear rate of 1200 seconds⁻¹.

### II. SUBSTRATE

Once formed, the polymer composition may be shaped into a variety of different types of substrates, such as sheets, films, molded parts, etc. Suitable shaping techniques may include, for instance, molding (e.g., injection molding, compression molding, etc.), profile extrusion, film or sheet forming, thermoforming, etc. In one embodiment, for instance, the substrate may be molded using a one-component injection molding process in which dried and preheated plastic granules are injected into the mold. Regardless of how it is formed, the substrate is typically thin in nature and may, for instance, have a thickness of about 10 millimeters or less, in some embodiments from about 0.01 to about 8 millimeters, in some embodiments from about 0.05 to about 6 millimeters, and in some embodiments, from about 0.1 to about 2 millimeters.

Due to its unique construction, the polymer composition may possess excellent mechanical properties, thereby facilitating its use in forming thin substrates. The composition may, for instance, possess a Charpy unnotched impact strength greater than about 6 kJ/m², in some embodiments from about 8 to about 50 kJ/m², and in some embodiments, from about 10 to about 45 kJ/m², measured at 23° C. according to ISO Test No. 179-1) (technically equivalent to ASTM D256, Method B). The tensile and flexural mechanical properties of the composition are also good. For example, the polymer composition may exhibit a tensile strength of from about 20 to about 500 MPa, in some embodiments from about 50 to about 400 MPa, and in some embodiments, from about 90 to about 350 MPa; a tensile elongation of about 0.5% or more, in some embodiments from about 0.6% to about 10%, and in some embodiments, from about 0.8% to about 3.5%; and/or a tensile modulus of from about 5,000 MPa o about 20,000 MPa, in some embodiments from about 8,000 MPa to about 20,000 MPa, and in some embodiments, from about 10,000 MPa to about 20,000 MPa. The tensile properties may be determined in accordance with ISO Test No. 527 (technically equivalent to ASTM D638) at 23° C. The polymer composition may also exhibit a flexural strength of from about 20 to about 500 MPa, in some embodiments from about 50 to about 400 MPa, and in some embodiments, from about 100 to about 350 MPa and/or a flexural modulus of from about 5,000 MPa to about 20,000 MPa, in some embodiments from about 8,000 MPa to about 20,000 MPa, and in some embodiments, from about 10,000 MPa to about 15,000 MPa. The flexural properties may be determined in accordance with ISO Test No. 178 (technically equivalent to ASTM D790) at 23° C.

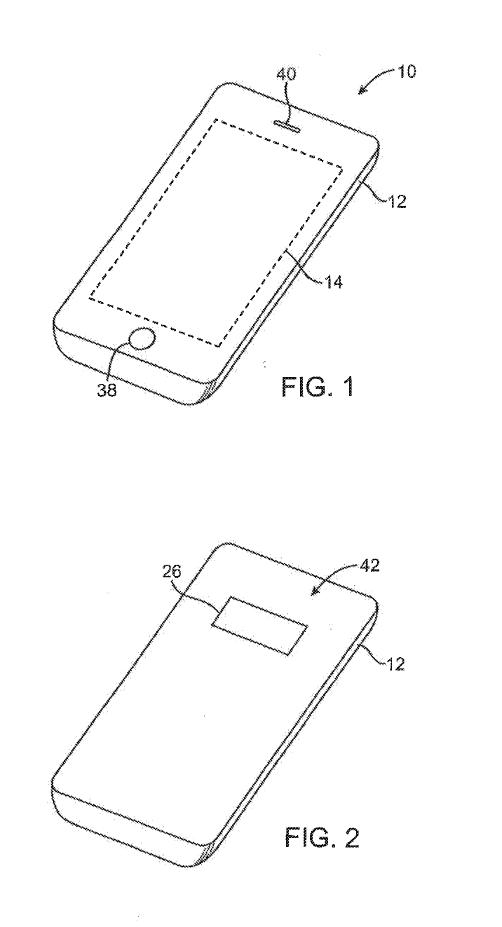

As indicated above, conductive elements may be formed on the substrate using a laser direct structuring process. Activation with a laser causes a physio-chemical reaction in which the spinel crystals are cracked open to release metal atoms. These metal atoms can act as a nuclei for metallization (e.g., reductive copper coating). The laser also creates a microscopically irregular surface and ablates the polymer matrix, creating numerous microscopic pits and undercuts in which the copper can be anchored during metallization. The resulting part may, for example, be a molded interconnect device (“MID”) or part in that it contains integrated electronic circuit conductive elements. One example of such a part is one in which the conductive elements form antennas of a variety of different types, such as antennae with resonating elements that are formed from patch antenna structures, inverted-F antenna structures, closed and open slot antenna structures, loop antenna structures, monopoles, dipoles, planar inverted-F antenna structures, hybrids of these designs, etc. One particularly suitable electronic component is shown in FIGS. 1-2 is a handheld device 10 with cellular telephone capabilities. As shown in FIG. 1, the device 10 may have a housing 12 formed from plastic, metal, other suitable dielectric materials, other suitable conductive materials, or combinations of such materials. A display 14 may be provided on a front surface of the device 10, such as a touch screen display. The device 10 may also have a speaker port 40 and other input-output ports. One or more buttons 38 and other user input devices may be used to gather user input. As shown in FIG. 2, an antenna structure 26 is also provided on a rear surface 42 of device 10, although it should be understood that the antenna structure can generally be positioned at any desired location of the device. The antenna structure may be electrically connected to other components within the electronic device using any of a variety of known techniques. Referring again to FIGS. 1-2, for example, the housing 12 or a part of housing 12 may serve as a conductive ground plane for the antenna structure 26.

Due to its unique properties, the molded part of the present invention may be employed in a wide variety of different electronic components. As an example, the molded part may be formed in electronic components, such as desktop computers, portable computers, handheld electronic devices, etc. In one suitable configuration, the part is formed in the housing of a relatively compact portable electronic component in which the available interior space is relatively small. Examples of suitable portable electronic components include cellular telephones, laptop computers, small portable computers (e.g., ultraportable computers, netbook computers, and tablet computers), wrist-watch devices, pendant devices, headphone and earpiece devices, media players with wireless communications capabilities, handheld computers (also sometimes called personal digital assistants), remote controllers, global positioning system (GPS) devices, handheld gaming devices, etc. The part could also be integrated with other components such as camera module, speaker or battery cover of a handheld device.

Apart from those referenced above, the molded part of the present invention may also be employed in a wide variety of other components, such as implantable medical devices. For example, the implantable medical device may be an active device, such as neurostimulators that are configured to provide a stimulation signal (e.g., therapeutic signal) to the central nervous system and/or peripheral nervous system, cardiac pacemakers or defibrillators, etc. Electrical neurostimulation may be provided by implanting an electrical device underneath the patient's skin and delivering an electrical signal to a nerve, such as a cranial nerve. The electrical signal may be applied by an implantable medical device that is implanted within the patient's body. In another alternative embodiment, the signal may be generated by an external pulse generator outside the patient's body, coupled by an RF or wireless link to an implanted electrode.

The present invention may be better understood with reference to the following examples.

### Test Methods

Deflection Under Load Temperature (“DTUL”):

The deflection under load temperature may be determined in accordance with ISO Test No. 75-1 (technically equivalent to ASTM D648-07). More particularly, a sample having a length of 80 mm, thickness of 10 mm, and width of 4 mm may be subjected to an edgewise three-point bending test in which the specified load is 1.8 MPa. The specimen may be lowered into a silicone oil bath where the temperature is raised at 2° C. per minute until it deflects 0.25 mm.

Tensile Modulus, Tensile Strength, and Tensile Elongation:

Tensile properties are tested according to ISO Test No. 527 (technically equivalent to ASTM D638). Modulus and strength measurements are made on the same test strip sample having a length of 80 mm, thickness of 10 mm, and width of 4 mm. The testing temperature is 23° C., and the testing speeds are 1 or 5 mm/min.

Flexural Modulus, Flexural Strength:

Flexural properties are tested according to ISO Test No. 178 (technically equivalent to ASTM D790). This test is performed on a 64 mm support span. Tests are run on the center portions of uncut ISO 3167 multi-purpose bars. The testing temperature is 23° C. and the testing speed is 2 mm/min.

Unnotched Charpy Impact Strength:

Unnotched Charpy properties are tested according to ISO Test No. 180 (technically equivalent to ASTM D256). The test is run using a Type 1 specimen (length of 80 mm, width of 10 mm and thickness of 4 mm). Specimens are cut from the center of a multi-purpose bare using a single tooth milling machine. The testing temperature is 23° C.

### Example 1

A concentrate is initially formed that contains 70 wt. % of a liquid crystalline polymer and 30 wt. % of a copper chromite filler (CuCr₂O₄) available from Shepherd Color Co. under the designation Shepherd 1G. The liquid crystalline polymer is formed from 4-hydroxybenzoic acid (“HBA”), 2,6-hydroxynaphthoic acid (“HNA”), terephthalic acid (“TA”), 4,4′-biphenol (“BP”), and acetaminophen (“APAP”), such as described in U.S. Pat. No. 5,508,374 to Lee et al. The polymer is pre-dried for a minimum of 4 hours at 140° C. A twin-screw extruder (Type Berstorff ZE25, 120 mm×25 mm with a main-feed, side-feed and degassing option) is used to compound the two components. The raw materials are initially introduced to the main feed of the extruder as pre-blends (obtained from a powder blender). Vacuum is applied through the vacuum-port of the extruder throughout the entire compounding operation. Once formed, the extruded strands are cooled in a water bath and then pelletized.

### Example 2

A concentrate is formed in the same manner described in Example 1, except that it contains 50 wt. % of the liquid crystalline polymer, 30 wt. % of a copper chromite black filler available from Shepherd Color Co. under the designation Dynamix® 30C965, and 20 wt. % mica (Arginotec® SE, dehydrated).

### Example

A polymer composition is formed from the concentrate of Example 1 such that the final composition contains 30 wt. % of the concentrate, 29.6 wt. % polyphenylene sulfide (Fortron® 0205B4 SF3001 Natural), 20 wt. % glass fibers (OCV 910, Owens Corning), 20 wt. % talc (HTP 4, IMI FABI) and 0.4 wt. % of triethoxy-aminopropylsilane. The same twin-screw extruder is used as in Example 1. The temperature of the feeding zone is 280° C., and the temperature of Zones 1-12 is 300° C., 300° C., 300° C., 300° C., 300° C., 290° C., 285° C., 310° C., 310° C., 310° C., 310° C., and 340° C., respectively. The screw speed is 200 to 250 rpm and the throughput is 25 kg/hr. The concentrate, PPS, talc, and silane are fed to the main feed, and the glass fibers are fed to a side feed.

### Example 4

A polymer composition is formed from the concentrate of Example 2 such that the final composition contains 30 wt. % of the concentrate, 39.6 wt. % polyphenylene sulfide (Fortron® 0205B4 SF3001 Natural), 20 wt. % glass fibers (OCV 910, Owens Corning), 10 wt. % mica (Arginotec® SE), and 0.4 wt. % of triethoxy-aminopropylsilane. The same twin-screw extruder is used as in Example 1. The same extruder and conditions are employed as in Example 3.

Once formed, the polymer compositions of Examples 3 and 4 are injection molded into a plaque having a size of 60 mm×60 mm×2 mm and then metallized using a laser direct structuring process. The quality of plating is determined by the average plating index (value of 1 means completely uniform plating) and the average adhesion of the metallized layer. For Example 3, the average plating index is 0.70 and the average adhesion is 0.66 N/mm, and for Example 4, the average plating index is 0.71 and the average adhesion is 0.80 N/mm. Various mechanical properties of the compositions are also tested as described above. The results are set forth below.

| | Example 3 | Example 4 |
|---|---|---|
| Tensile Modulus (MPa) | 13,800 | 11,000 |
| Tensile Strength (MPa) | 105 | 95 |
| Tensile Elongation (%) | 1.0 | 1.1 |
| Flexural Modulus (MPa) | 13,900 | 10,200 |
| Flexural Strength (MPa) | 149 | 132 |
| Unnotched Charpy Impact Strength (kJ/m²) | 15 | 14 |
| DTUL (° C.) | 260 | 255 |

### Example 5

A concentrate is initially formed that contains 50 wt. % of a liquid crystalline polymer, 30 wt. % of a copper chromite filler (CuCr₂O₄) available from Shepherd Color Co. under the designation Shepherd Dynamix 30C965, and 20 wt. % of a silicate mineral filler (Arginotech SE Dehydrated). A polymer composition is formed from the concentrate such that the final composition contains 30 wt. % of the concentrate, 39.3 wt. % polyphenylene sulfide (Fortron® 0205B4 SF3001 Natural), 20 wt. % glass fibers, 10 wt. % a silicate mineral filler (Arginotech SE Dehydrated), 0.4 wt. % of triethoxyaminopropylsilane, and 0.3 wt. % Glycolube™ P. Once formed, the polymer composition is injection molded into a plaque having a size of 60 mm×60 mm×2 mm and then metallized using a laser direct structuring process. The quality of plating is determined by the average plating index (value of 1 means completely uniform plating) and the average adhesion of the metallized layer. The average plating index is 0.70 and the average adhesion is 0.7-0.8 N/mm. Various mechanical properties of the compositions are also tested as described above. The results are set forth below.

| | Example 5 |
|---|---|
| Tensile Modulus (MPa | 11,300 |
| Tensile Strength (MPa) | 103 |
| Tensile Elongation (%) | 1.1 |
| Flexural Modulus (MPa) | 11,000 |
| Flexural Strength (MPa) | 148 |
| Unnotched Charpy Impact Strength (kJ/m²) | 17 |
| DTUL (° C.) | 255 |

These and other modifications and variations of the present invention may be practiced by those of ordinary skill in the art, without departing from the spirit and scope of the present invention. In addition, it should be understood that aspects of the various embodiments may be interchanged both in whole or in part. Furthermore, those of ordinary skill in the art will appreciate that the foregoing description is by way of example only, and is not intended to limit the invention so further described in such appended claims.

What is claimed is:

1. A polymer composition comprising a polyarylene sulfide matrix within which is dispersed a condensation polymer and a laser activatable additive, wherein the polyarylene sulfide matrix constitutes about 30 wt. % or more of the polymer content of the composition.

2. The polymer composition of claim 1, wherein the polyarylene sulfide matrix includes polyphenylene sulfide.

3. The polymer composition of claim 1, wherein the weight ratio of polyarylene sulfides to condensation polymers in the polymer composition ranges from about 0.5 to about 1.0.

4. The polymer composition of claim 1, wherein polyarylene sulfides constitute from about 15 wt. % to about 75 wt. % of the polymer composition.

5. The polymer composition of claim 1, wherein condensation polymers constitute from about 1 wt. % to about 30 wt. % of the polymer composition.

6. The polymer composition of claim 1, wherein the condensation polymer includes an aliphatic, aromatic, and/or aliphatic-aromatic polyester, polyamide, polyacrylamide, polyimide, or a combination thereof.

7. The polymer composition of claim 1, wherein the condensation polymer is an aromatic polyester.

8. The polymer composition of claim 7, wherein the aromatic polyester is a liquid crystalline polymer.

9. The polymer composition of claim 8, wherein the liquid crystalline polymer contains aromatic ester repeating units, the aromatic ester repeating units including aromatic dicarboxylic acid repeating units and aromatic hydroxycarboxylic acid repeating units.

10. The polymer composition of claim 9, wherein the aromatic hydroxycarboxylic acid repeating units are derived from 4-hydroxybenzoic acid, 6-hydroxy-2-naphthoic acid, or a combination thereof and/or the aromatic dicarboxylic acid repeating units are derived from terephthalic acid, isophthalic acid, or a combination thereof.

11. The polymer composition of claim 10, wherein the liquid crystalline polymer further contains hydroquinone, 4,4′-biphenol, or a combination thereof.

12. The polymer composition of claim 7, wherein the aromatic polyester is poly(ethylene terephthalate), poly(butylene terephthalate), poly(trimethylene terephthalate), poly(ethylene naphthalate), poly(cyclohexanedimethanol terephthalate), or a combination thereof.

13. The polymer composition of claim 1, wherein the laser activatable additive includes a spinel crystal.

14. The polymer composition of claim 13, wherein the crystal has the following general formula:
AB₂O₄
wherein,
A is a metal cation having a valance of 2; and
B is a metal cation having a valance of 3.

15. The polymer composition of claim 14, wherein the spinel crystal is MgAl₂O₄, ZnAl₂O₄, FeAl₂O₄, CuFe₂O₄, CuCr₂O₄, MnFe₂O₄, NiFe₂O₄, TiFe₂O₄, FeCr₂O₄, MgCr₂O₄, or a combination thereof.

16. The polymer composition of claim 1, wherein laser activatable additives constitute from about 0.5 wt. % to about 30 wt. % of the polymer composition.

17. The polymer composition of claim 1, wherein the polymer composition comprises a mineral filler, fibrous filler, or a combination thereof.

18. The polymer composition of claim 17, wherein the polymer composition includes talc, mica, or a combination thereof.

19. A substrate comprising the polymer composition of claim 1.

20. The substrate of claim 19, wherein the substrate is injection molded.

21. A circuit comprising conductive elements disposed on a surface of the substrate of claim 19.

22. A method for forming the polymer composition of claim 1, the method comprising pre-blending the laser activatable additive with the condensation polymer to form a masterbatch, and thereafter blending the masterbatch with the polyarylene sulfide matrix to form the polymer composition.

23. The method of claim 22, wherein the masterbatch further includes a mineral filler, fibrous filler, or a combination thereof.
